(19) United States
(12) Patent Application Publication
(10) Pub. No.: US 2026/0082921 A1
(43) Pub. Date: Mar. 19, 2026

(54) SEMICONDUCTOR MODULE

(71) Applicant: FUJI ELECTRIC CO., LTD., Kawasaki-shi (JP)

(72) Inventor: Yuhei NISHIDA, Kawasaki-shi, Kanagawa (JP)

(73) Assignee: FUJI ELECTRIC CO., LTD., Kawasaki-shi (JP)

(21) Appl. No.: 19/283,940

(22) Filed: Jul. 29, 2025

(30) Foreign Application Priority Data
Sep. 17, 2024 (JP) 2024-159705

(51) Int. Cl. H01L 23/00; H01L 23/367; H01L 23/373; H01L 23/492; H01L 25/07; H01L 25/18; H10D 80/20

(52) U.S. Cl. CPC H10W 42/121; H10D 80/20; H10W 40/226; H10W 40/255; H10W 70/20; H10W 90/00; H10W 90/753; H10W 90/754

(57) ABSTRACT

A semiconductor module includes a wiring board having a semiconductor element mounted thereon, and a heat dissipation base bonded to the wiring board via a bonding material. In a cross section passing through corners both an insulating layer of the wiring board and a second conductor layer on the insulating layer in plan view, in a horizontal direction, a distance from the second conductor layer to a peripheral edge of the bonding material on the second conductor layer is equal to or less than a thickness of the bonding material between the second conductor layer and the heat dissipation base, and a distance from the second conductor layer to a non-bonded region provided on the heat dissipation base around the bonding material is equal to or less than a distance from the second conductor layer to a peripheral edge of the insulating layer on a second surface.

### CROSS-REFERENCE TO RELATED APPLICATIONS

This application is based upon and claims the benefit of priority to Japanese Patent Application No. 2024-159705, filed on Sep. 17, 2024, the entire contents of which are incorporated herein by reference.

### BACKGROUND OF THE INVENTION

### 1. Technical Field

The present invention relates to a semiconductor module that includes a wiring board on which a semiconductor element is mounted and a heat dissipation base bonded to the wiring board.

### 2. Description of Related Art

Typically, as a semiconductor module used for a power converter or the like, a semiconductor module or the like has been known in which a wiring board on which a semiconductor element is mounted is bonded to a heat dissipation base (for example refer to JP 2013-197432 A, JP 2022-024309 A, JP 2012-114203 A, JP 2005-039081 A, JP 2004-134746 A, and JP 7233604 B). In this type of semiconductor module, the wiring board includes an insulating layer such as a ceramic substrate provided with conductor layers on a front and a rear sides and is bonded to the heat dissipation base with a bonding material such a solder on a rear surface side of the wiring board.

### SUMMARY OF THE INVENTION

When a bonding material for bonding a wiring board to a heat dissipation base is crushed during melting due to a weight of the wiring board, a mounted part, and a jig, a contact area with an insulating layer increases. Then, at the time when the bonding material is cooled (at the time of heat shrinking), the insulating layer having a relatively small linear expansion coefficient is pulled by the bonding material and a conductor layer having a relatively large linear expansion coefficient. Since the insulating layer is not bonded to the bonding material, a stress concentrates at a boundary between the bonding material and the conductor layer so that a crack may occur.

According to one aspect, an object of the present invention is to provide a semiconductor module that can suppress occurrence of a crack in an insulating layer of a wiring board.

A semiconductor module according to one mode includes a semiconductor element, a wiring board on which the semiconductor element is mounted, and a heat dissipation base bonded to the wiring board with a bonding material, in which the wiring board includes an insulating layer, a first conductor layer provided on a first surface of the insulating layer on a side of the semiconductor element, and a second conductor layer provided on a second surface of the insulating layer on a side of the heat dissipation base, in a cross section passing through a corner of the insulating layer in plan view and the corner of the second conductor layer, a distance from the second conductor layer to a peripheral edge of the bonding material on the second surface is equal to or less than a thickness of the bonding material between the second conductor layer and the heat dissipation base, a non-bonded portion is provided around the bonding material on the heat dissipation base, wettability between the bonding material and the second conductor layer and wettability between the bonding material and the heat dissipation base are larger than wettability between the non-bonded portion and the bonding material, and in the cross section, a distance from the second conductor layer to the non-bonded portion in plan view is equal to or less than a distance from the second conductor layer to a peripheral edge of the insulating layer on the second surface.

A semiconductor module according to another mode includes a semiconductor element, a wiring board on which the semiconductor element is mounted, and a heat dissipation base bonded to the wiring board with a bonding material, in which the wiring board includes an insulating layer, a first conductor layer provided on a first surface of the insulating layer on a side of the semiconductor element, and a second conductor layer provided on a second surface of the insulating layer on a side of the heat dissipation base, and in a cross section passing through a corner of the insulating layer in plan view and the corner of the second conductor layer, a distance from the second conductor layer to a peripheral edge of the insulating layer on the second surface is equal to or less than a thickness of the bonding material between the second conductor layer and the heat dissipation base.

According to the above mode, it is possible to suppress occurrence of a crack in an insulating layer of a wiring board.

### BRIEF DESCRIPTION OF THE DRAWINGS

FIG. 1 is a plan view of a semiconductor module according to an embodiment;

FIG. 2 is a cross-sectional view taken along a line II-II in FIG. 1;

FIG. 3 is a plan view illustrating a solder resist provided on a heat dissipation base at an adjacent portion of a plurality of insulating layers, according to the embodiment;

FIG. 4 is a plan view illustrating a solder resist provided on the heat dissipation base only at an adjacent portion of corners of the plurality of insulating layers, according to the embodiment;

FIG. 5 is a plan view illustrating the solder resist on the heat dissipation base, according to the embodiment;

FIG. 6 is a cross-sectional view for explaining an increase in a contact area between a bonding material and the insulating layer at a center of the heat dissipation base;

FIG. 7 is a cross-sectional view for explaining spread of the bonding material in a comparative example (in a case of no solder resist);

FIG. 8 is a cross-sectional view for explaining occurrence of a crack in the comparative example;

FIG. 9 is a diagram illustrating an example of a maximum main stress of the insulating layer according to the embodiment and the comparative example;

FIG. 10 is a plan view illustrating the solder resist on the heat dissipation base, according to a first modification of the embodiment;

FIG. 11 is a plan view illustrating the solder resist on the heat dissipation base, according to a second modification of the embodiment; and

FIG. 12 is a cross-sectional view (corresponding to line II-II in FIG. 1) illustrating a wiring board or the like according to other embodiments.

### DETAILED DESCRIPTION

Hereinafter, a semiconductor module 1 according to an embodiment and other embodiments of the present invention will be described in detail with reference to the drawings. Note that each axis of X, Y, and Z in each figure to be referred is illustrated for the purpose of defining a direction or each plane in the illustrated semiconductor module 1 or the like. The X, Y, and Z axes are orthogonal to each other and form a right-handed system. In the following description, a Z direction may be referred to as a vertical direction. Furthermore, a surface including the X axis and the Y axis may be referred to as an upper surface or a lower surface.

Such directions and planes are terms used for convenience of description. Thus, depending on an attachment posture of the semiconductor module 1 or the like, a correspondence relationship with the X, Y, and Z directions may vary. For example, here, a surface facing a Z direction positive side (+Z direction) in a member forming the semiconductor module 1 is referred to as an upper surface, and a surface facing a Z direction negative side (−Z direction) is referred to as a lower surface. However, the surface facing the Z direction negative side may be referred to as the upper surface, and the surface facing the Z direction positive side may be referred to as the lower surface. Furthermore, here, the plan view means a case where the upper surface (XY plane) of the semiconductor module 1 or the like is viewed in a perspective manner from the Z direction positive side toward the Z direction negative side.

An aspect ratio and a magnitude relationship between respective members in each figure are merely schematically represented, and do not necessarily coincide with a relationship in the semiconductor module 1 or the like actually manufactured. For convenience of description, there is a case where the magnitude relationship between the members might be exaggerated. In addition, the shapes of the same members may be different between different drawings.

In the following description, as an example of the semiconductor module 1 according to the embodiment and the other embodiments, a device is exemplified that is applied to a power converter such as an industrial or an in-vehicle motor inverter device. Therefore, in the following description, detailed description of the same or similar configuration, function, operation, assembly method, and the like as or to those of a known semiconductor module will be omitted.

### Embodiment

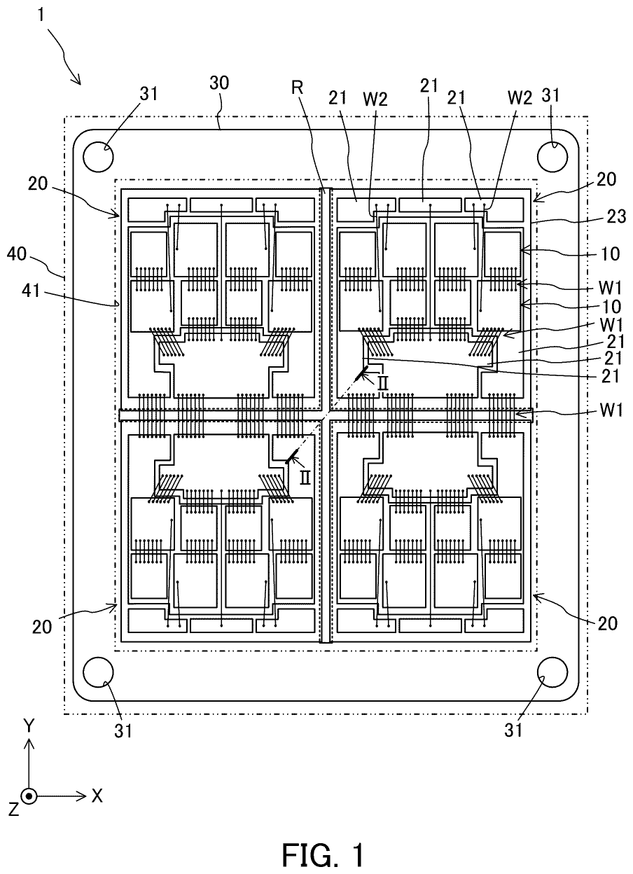

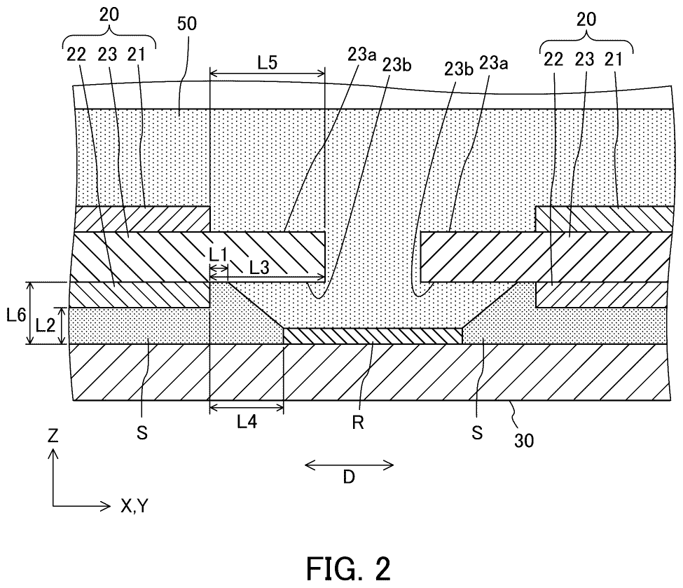

FIG. 1 is a plan view illustrating a semiconductor module 1 according to an embodiment. FIG. 2 is a cross-sectional view taken along a line II-II of FIG. 1.

The semiconductor module 1 illustrated in FIG. 1 includes a plurality of semiconductor elements 10, a plurality of wiring boards 20, and a heat dissipation base 30. Furthermore, the semiconductor module 1 includes a case 40 (illustrated by dash-double-dot line that is imaginary line) and a sealing material 50 illustrated in FIG. 2.

The semiconductor element 10 is mounted on the wiring board 20. In the example in FIG. 1, the semiconductor module 1 includes the four wiring boards 20 aligned by two in each an X direction and a Y direction and the semiconductor elements 10 aligned by eight on each of the four wiring boards 20.

For example, the semiconductor element 10 is an insulated gate bipolar transistor (IGBT) that is a switching element, a free wheeling diode (FWD) element that is a diode element, or the like. As the semiconductor element 10, another semiconductor element such as a reverse conducting (RC)-IGBT element in which the switching element and the diode element connected in antiparallel to the switching element are integrated may be arranged. The switching element and the diode element in the semiconductor element 10 are not limited to be formed on a Si substrate, and may be formed on a semiconductor substrate using a wide band gap semiconductor such as Silicon Carbide (SiC) or Gallium Nitride (GaN), for example. Furthermore, the switching element may include, for example, a SiC metal oxide semiconductor field effect transistor (MOSFET), a bipolar junction transistor (BJT), or the like. Furthermore, the diode element may include, for example, a schottky barrier diode (SiC-SBD), a junction barrier schottky (JBS) diode, a merged PN schottky (MPS) diode, a PN diode, or the like.

A main electrode provided on an upper surface of the semiconductor element 10 is electrically connected to the another semiconductor element 10, a first conductor layer 21, or the like by a main current wiring line W1. Furthermore, a control electrode (for example, gate electrode) provided on the upper surface of the semiconductor element 10 is electrically and indirectly or directly connected to a control terminal (not illustrated) via the first conductor layer 21 by a control wiring line W2. It is preferable that a main terminal that is an input terminal or an output terminal of the semiconductor module 1 and the control terminal be, for example, integrally fixed to the case 40 (illustrated by dash-double-dot line that is imaginary line) to be described later that covers around the four wiring boards 20.

Each of the four wiring boards 20 is bonded to the single common heat dissipation base 30, with a bonding material S such as solder, on a lower surface (second conductor layer 22). The wiring board 20 has a rectangular shape in plan view and includes the first conductor layer 21, the second conductor layer 22, and an insulating layer 23. The wiring board 20 may be, for example, a direct copper bonding (DCB) substrate or an active metal brazing (AMB) substrate. The wiring board 20 may be referred to as a laminated substrate, an insulating circuit substrate, an insulating heat dissipation circuit substrate, or the like.

The first conductor layer 21 is, for example, a member that functions as a wiring member in an inverter circuit and is provided to be separated as a plurality of parts on a first surface 23a of the insulating layer 23 on a side of the semiconductor element 10 by a metal plate, a metal foil, or the like of copper, aluminum, or the like. The first conductor layer 21 is electrically connected to the another first conductor layer 21, the main electrode, the main terminal, the control terminal, or the like provided on the upper surface of the semiconductor element 10, by the main current wiring line W1 or the control wiring line W2. The first conductor layer 21 may be referred to as a conductor plate, a conductor pattern, a conductive layer, a wiring pattern, or the like. The main current wiring line W1 and the control wiring line W2 are, for example, metallic bonding wires. The main current wiring line W1 and the control wiring line W2 (in particular, main current wiring line W1) may be replaced with another wiring line such as a lead formed by processing a metal plate such as a copper plate.

The second conductor layer 22 is, for example, a member that functions as a heat conducting member that conducts heat generated in the inverter circuit to the heat dissipation base 30 and is provided on a second surface 23b of the insulating layer 23 on a side of the heat dissipation base 30 by a metal plate, a metal foil, or the like of copper, aluminum, or the like. The second conductor layer 22 (wiring board 20) is bonded to the heat dissipation base 30 with the bonding material S such as solder. The second conductor layer 22 may be referred to as a heat dissipation layer, a heat dissipation plate, a heat dissipation pattern, a conductor pattern, or the like.

The insulating layer 23 is, for example, a ceramic substrate. Although the insulating layer 23 is not limited to a specific substrate, the insulating layer 23 may be, for example, a ceramic substrate formed of a ceramic material such as aluminum nitride (AlN), aluminum oxide (Al₂O₃), silicon nitride (Si₃N₄), or a composite material of aluminum oxide (Al₂O₃) and zirconium oxide (ZrO₂). The insulating layer 23 may be, for example, a substrate obtained by molding an insulating resin such as an epoxy resin, a substrate obtained by impregnating a base material such as a glass fiber with an insulating resin, a substrate obtained by coating a surface of a flat plate-shaped metal core with an insulating resin, or the like. Here, the bonding material S that is used to bond the wiring board 20 to the heat dissipation base 30 covers the second conductor layer 22 and has contact with the insulating layer 23. However, the bonding material S does not need to have contact with the insulating layer 23.

Note that a shape, the arranged number, an arrangement location, or the like of the semiconductor element 10 and the wiring board 20 can be appropriately changed. It is desirable that the plurality of wiring boards 20 be arranged. However, the numbers of semiconductor elements 10 and wiring boards 20 may be any number of one or more.

The heat dissipation base 30 has a rectangular shape in plan view. In the heat dissipation base 30, fastening holes 31 are provided at four corners in plan view. The heat dissipation base 30 is fastened to a cooler (not illustrated) together with the case 40, with a screw to be inserted into the fastening hole 31.

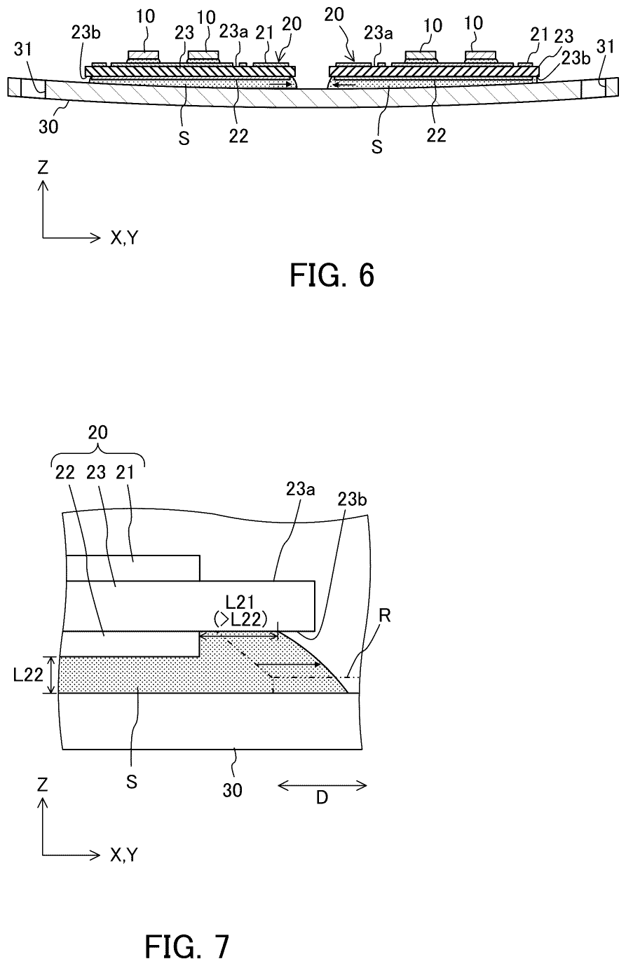

The heat dissipation base 30 is a member that functions as a heat conducting member that conducts heat generated by the semiconductor element 10 to the cooler, and is formed of a metal plate such as a copper plate or an aluminum plate, for example. In order to radially push and spread a thermal conductive material such as thermal grease or a thermal compound to be inserted between the heat dissipation base 30 and the cooler from the center of the heat dissipation base 30, as illustrated in FIG. 6, the entire heat dissipation base 30 is warped, for example, by press working so that a lower surface of a metal plate having a flat plate shape becomes a convex curved surface and an upper surface becomes a concave curved surface. After being fastened to the cooler with the screw to be inserted into the fastening hole 31, the shape of the heat dissipation base 30 becomes closer to a flat plate shape as illustrated in FIG. 2.

For example, the case 40 has a quadrangular cylindrical shape of which a center axis is the Z direction and houses the semiconductor element 10 and the wiring board 20 in a hollow portion 41. For example, the case 40 is fixed to a peripheral edge of the upper surface of the heat dissipation base 30 by adhesion and is fastened to the cooler together with the heat dissipation base 30.

The sealing material 50 illustrated in FIG. 2 seals the semiconductor element 10 and the wiring board 20, in the case 40. The sealing material 50 is, for example, an epoxy resin, silicone gel, or the like.

As illustrated in FIG. 2, a solder resist R is provided around the bonding material S on the heat dissipation base 30. Since the solder resist R has a property for repelling the bonding material S even in contact with the bonding material S, the solder resist R is not bonded to the bonding material S. Note that the solder resist R is an example of a non-bonded portion. The non-bonded portion is not limited to the solder resist R, as long as the non-bonded portion is a processed portion where the bonding material S and the heat dissipation base 30 are not bonded. For example, the non-bonded portion may be a portion filled with a pencil or the like (coated portion with filling material such as graphite), an oxide film, or the like. Here, wettability between the solder resist R (non-bonded portion) and the bonding material S is lower than wettability between the bonding material S and the first conductor layer 21, the second conductor layer 22, and the heat dissipation base 30. Furthermore, the wettability between the solder resist R and the bonding material S is more preferably lower than wettability between the bonding material S and the insulating layer 23.

The solder resist R is arranged around the bonding material S on the heat dissipation base 30, for example, between the adjacent wiring boards 20 (insulating layer 23), in plan view. In the example illustrated in FIG. 1, since the two wiring boards 20 are aligned in each of the X direction and the Y direction, the solder resist R has a cross shape in plan view. However, the solder resist R may be provided so as to surround the bonding material S, over an entire circumference of the wiring board 20.

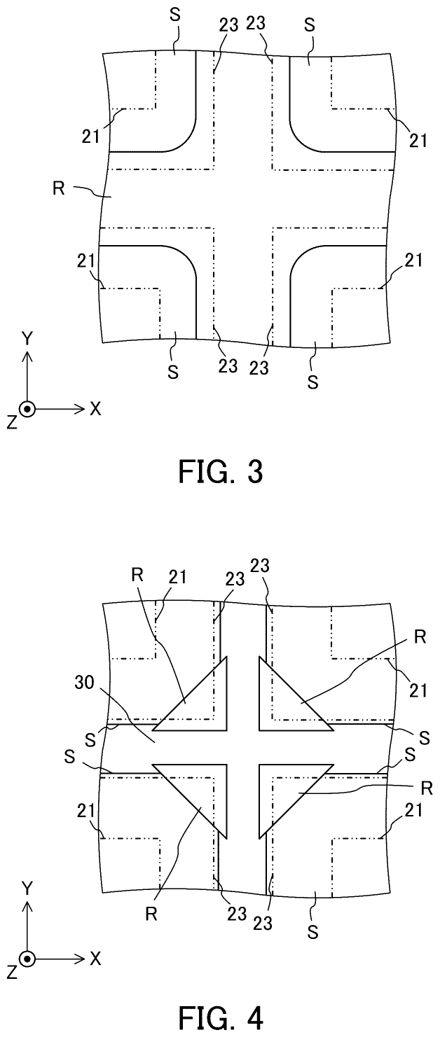

It is preferable that the solder resist R be provided with a width that the bonding material S does not pass over. Furthermore, in order to prevent connection of the bonding material S between the adjacent wiring boards 20, it is sufficient that the solder resist R be arranged in the cross shape described above across an entire region between the adjacent insulating layers 23, in plan view, as illustrated in FIGS. 1 and 3. Furthermore, as illustrated in FIG. 4, the solder resist R may be arranged only at the corner of the insulating layer 23, in plan view. This corner may be only a portion where the corners of the two or four insulating layers 23 face each other or may be only a portion where the corners of the four insulating layers 23 face each other. Although the solder resist R illustrated in FIG. 4 has a right triangle having two sides parallel to a peripheral edge of the insulating layer 23 in plan view, the solder resist R may have any shape. Note that, in FIGS. 3 and 4, since the first conductor layer 21 and the insulating layer 23 are located above the bonding material S and the solder resist R, the first conductor layer 21 and the insulating layer 23 are illustrated as dash-double-dot lines that are imaginary lines.

Here, as illustrated in FIG. 2, in a II-II cross section in FIG. 1 (cross section passing through corner of insulating layer 23 in plan view and corner of second conductor layer 22), a distance (length L1) from the second conductor layer 22 to a peripheral edge of the bonding material S on the second surface 23b of the insulating layer 23 is equal to or less than a thickness (length L2) of the bonding material S between the second conductor layer 22 and the heat dissipation base 30. Note that the cross section in FIG. 2 extends in a diagonal direction D of the insulating layer 23 in plan view. Furthermore, although the peripheral edges of the bonding material S and the insulating layer 23 on the cross section can be said as the corner, the peripheral edges may be curved.

Furthermore, in the cross section in FIG. 2, a distance (length L4) from the second conductor layer 22 to the solder resist R (same as distance to peripheral edge of bonding material S on heat dissipation base 30) in plan view (direction orthogonal to thickness direction (Z direction) of bonding material S (in XY plane)) is equal to or less than a distance (length L3) from the second conductor layer 22 to the peripheral edge of the insulating layer 23 on the second surface 23b. Note that, if the length L4 is shorter than the length L3, the solder resist R is located below the insulating layer 23. As an example, the length L4 is equal to or less than 1 mm.

Furthermore, in the cross section in FIG. 2, the distance (length L4) from the second conductor layer 22 to the peripheral edge of the bonding material S on the heat dissipation base 30 (same as distance to solder resist R) in plan view is shorter than a distance (length L5) from the first conductor layer 21 to the peripheral edge of the first surface 23a of the insulating layer 23.

Furthermore, in the cross section in FIG. 2, the distance (length L4) from the second conductor layer 22 to the peripheral edge of the bonding material S on the heat dissipation base 30 (same as distance to solder resist R) in plan view is longer than a distance (length L6) between the insulating layer 23 and the heat dissipation base 30 in the thickness direction (Z direction) of the bonding material S.

Furthermore, in the cross section in FIG. 2, although the distance (length L5) from the first conductor layer 21 to the peripheral edge of the first surface 23a of the insulating layer 23 is substantially the same as the distance (length L3) from the second conductor layer 22 to the peripheral edge of the insulating layer 23 of the second surface 23b in FIG. 2, the distance (length L5) is preferably longer than the length L3.

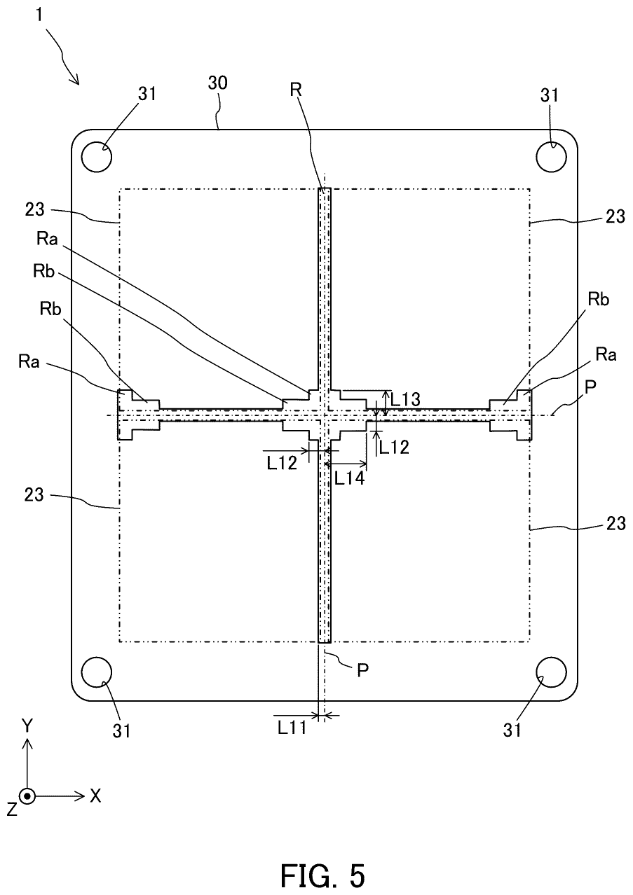

Here, the peripheral edge (corner) of the insulating layer 23 on the cross section in FIG. 2 is preferably a portion adjacent to the another insulating layer 23. Furthermore, as illustrated in FIG. 5, the solder resist R preferably has a longitudinal direction wide portion Ra and a lateral direction wide portion Rb, in a portion where the corners of the two or four insulating layers 23 are adjacent to each other. The longitudinal direction wide portion Ra extends in a longitudinal direction (Y direction) of the heat dissipation base 30, and the lateral direction wide portion Rb extends in a lateral direction (X direction) of the heat dissipation base 30. In the solder resist R, a width (length L12) from an intermediate position P of the longitudinal direction wide portion Ra and the lateral direction wide portion Rb is longer than widths (length L11) from an intermediate position P of the two insulating layers 23 in a portion where sides of the two insulating layers 23 are adjacent to each other. Furthermore, a length (L13) of the longitudinal direction wide portion Ra extending in the longitudinal direction (Y direction) is longer than the widths (length L12) from the intermediate position P of the longitudinal direction wide portion Ra and the lateral direction wide portion Rb. Furthermore, a length (L14) of the lateral direction wide portion Rb extending in the lateral direction (X direction) is, for example, twice or more than the length (L13) of the longitudinal direction wide portion Ra extending in the longitudinal direction (Y direction). Note that the longitudinal direction wide portion Ra and the lateral direction wide portion Rb may be provided only in a portion where the corners of the four insulating layers 23 are adjacent to each other. Furthermore, only the lateral direction wide portion Rb, of the longitudinal direction wide portion Ra and the lateral direction wide portion Rb, may be provided. Furthermore, in a case where the heat dissipation base 30 has a square shape in plan view or the like, the lengths of the wide portions (longitudinal direction wide portion Ra and lateral direction wide portion Rb) may be the same.

Since the lower surface of the heat dissipation base 30 is a convex curved surface and the upper surface is warped to be a concave curved surface, as illustrated in FIG. 6, the bonding material S at the time of melting gathers at the center of the heat dissipation base 30 in plan view due to the gravity (refer to arrow in FIG. 6). A fillet easily spreads in a portion where an amount of the bonding material S increases, and the wiring board 20 sinks due to weights of the wiring board 20 (semiconductor element 10) and a jig so that the insulating layer 23 (second surface 23b) and the bonding material S easily come into contact with each other. On the other hand, since the amount of the bonding material S is small in the peripheral edge of the heat dissipation base 30, the fillet becomes smaller, and a contact area between the bonding material S and the insulating layer 23 hardly increases even if the wiring board 20 sinks.

In this respect, as described above, the solder resist R is arranged between the adjacent wiring boards 20 (insulating layer 23). Therefore, it is possible to suppress the spread of the bonding material S, in a portion on a center side of the heat dissipation base 30 where the contact area with the insulating layer 23 is likely to increase, than a portion on a peripheral edge side of the heat dissipation base 30 where the wiring board 20 is not adjacent to the other wiring board 20. Furthermore, as illustrated in FIG. 5, the length (L14) of the lateral direction wide portion Rb extending in the lateral direction (X direction) is longer than the length (L13) of the longitudinal direction wide portion Ra extending in the longitudinal direction (Y direction). As a result, since the wide portion of the solder resist R (lateral direction wide portion Rb) is lengthened at the center in the longitudinal direction of the heat dissipation base 30 where the contact area with the insulating layer 23 is particularly likely to increase, it is possible to further suppress the spread of the bonding material S.

When the solder resist R is omitted (positions of solder resist R and bonding material S in a case where this solder resist R is provided are illustrated by dash-double-dot lines that are imaginary lines) as in a comparative example illustrated in FIG. 7, in the cross section, a distance (length L21) from the second conductor layer 22 to the peripheral edge of the bonding material S on the second surface 23b of the insulating layer 23 is longer than a thickness (length L22) of the bonding material S between the second conductor layer 22 and the heat dissipation base 30.

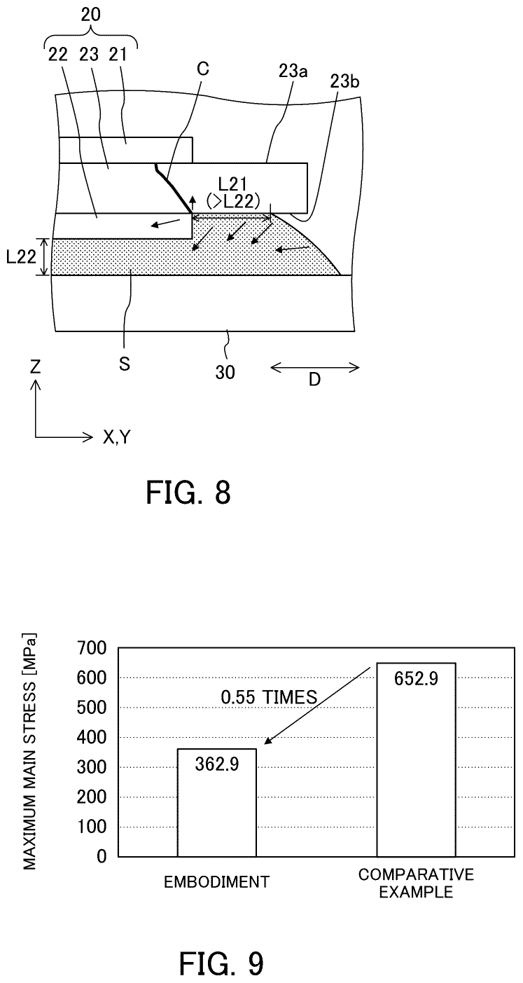

As a result, at the time of cooling the insulating layer 23, as illustrated in FIG. 8, the insulating layer 23 having a relatively small linear expansion coefficient is pulled by the bonding material S and the second conductor layer 22 having a relatively large linear expansion coefficient. Then, since the insulating layer 23 is not bonded with the bonding material S, a stress concentrates at a boundary between the bonding material S and the second conductor layer 22, and a crack C occurs in the insulating layer 23. This crack C is likely to occur in a case where the insulating layer 23 includes a material with low flexural strength such as AlN-based ceramic.

On the other hand, by providing the solder resist R as in the present embodiment, in the cross section illustrated in FIG. 2, the distance (length L1) from the second conductor layer 22 to the peripheral edge of the bonding material S on the second surface 23b of the insulating layer 23 is equal to or less than the thickness (length L2) of the bonding material S between the second conductor layer 22 and the heat dissipation base 30, and the stress of the insulating layer 23 during a heat cycle is relaxed. Therefore, as illustrated in FIG. 9, in the present embodiment, as compared with a mode in which the length L21 (corresponding to length L1) is longer than the length L22 (corresponding to length L2) as in the comparative example illustrated in FIG. 7, a maximum main stress [MPa] of the insulating layer 23 is reduced to about 0.55 times (652.9 →362.9). As a result, a ceramic crack occurrence rate caused by heating and cooling during an operation of the semiconductor module 1 is reduced, for example, from 80% to 10 Parts Per Million (ppm) or less, and quality is improved.

In the embodiment described above, the semiconductor module 1 includes the semiconductor element 10, the wiring board 20 on which the semiconductor element 10 is mounted, and the heat dissipation base 30 bonded to the wiring board 20 with the bonding material S. The wiring board 20 includes the insulating layer 23, the first conductor layer 21 provided on the first surface 23a of the insulating layer 23 on the semiconductor element 10 side, and the second conductor layer 22 provided on the second surface 23b of the insulating layer 23 on the heat dissipation base 30 side. In the cross section (refer to FIG. 2) passing through the corner of the insulating layer 23 in plan view and the corner of the second conductor layer 22, the distance (length L1) from the second conductor layer 22 to the peripheral edge of the bonding material S on the second surface 23b of the insulating layer 23 is equal to or less than the thickness (length L2) of the bonding material S between the second conductor layer 22 and the heat dissipation base 30. Around the bonding material S on the heat dissipation base 30, the solder resist R (example of non-bonded portion) is provided. The wettability between the bonding material S and the second conductor layer 22 and between the bonding material S and the heat dissipation base 30 is larger than the wettability between the solder resist R and the bonding material S. More preferably, the wettability between the solder resist R and the bonding material S is lower than the wettability between the insulating layer 23 and the bonding material S. In the cross section, the distance (length L4) from the second conductor layer 22 to the solder resist R in plan view is equal to or less than the distance (length L3) from the second conductor layer 22 to the peripheral edge of the insulating layer 23 on the second surface 23b.

As a result, the solder resist R is located below the insulating layer 23 or around the peripheral edge, so that, in the cross section in FIG. 2, the distance (length L1) from the second conductor layer 22 to the peripheral edge of the bonding material S on the second surface 23b of the insulating layer 23 can be equal to or less than the thickness (length L2) of the bonding material S between the second conductor layer 22 and the heat dissipation base 30. Therefore, at the time when the bonding material S is cooled (at the time of heat shrinking), at the corner of the insulating layer 23 where the stress easily concentrates, even if the insulating layer 23 having the relatively small linear expansion coefficient is pulled by the bonding material S and the second conductor layer 22 having the relatively large linear expansion coefficient, the stress concentrating at the boundary between the bonding material S and the second conductor layer 22 in the insulating layer 23 can be relaxed. Therefore, according to the present embodiment, it is possible to suppress the occurrence of the crack C in the insulating layer 23 of the wiring board 20.

Furthermore, in the present embodiment, the semiconductor module 1 includes the plurality of wiring boards 20, and the corner of the insulating layer 23 on the cross section is adjacent to the another insulating layer 23.

As a result, in a portion where the plurality of insulating layers 23 is adjacent to each other and where the stress is easily concentrated, the stress concentrating at the boundary between the bonding material S and the second conductor layer 22 in the insulating layer 23 can be relaxed. Therefore, it is possible to further suppress the occurrence of the crack C in the insulating layer 23 of the wiring board 20.

Furthermore, in the present embodiment, in the cross section, the distance (length L4) from the second conductor layer 22 to the peripheral edge (solder resist R) of the bonding material S on the heat dissipation base 30 in plan view is shorter than the distance (length L5) from the first conductor layer 21 to the peripheral edge of the first surface 23a of the insulating layer 23.

As a result, even if the spread of the bonding material S increases and the contact area between the bonding material S and the second surface 23b of the insulating layer 23 increases, an insulating distance along a surface of the insulating layer 23 can be secured.

Furthermore, in the present embodiment, in the cross section, the distance (length L4) from the second conductor layer 22 to the peripheral edge (solder resist R) of the bonding material S on the heat dissipation base 30 in plan view is longer than the distance (length L6) between the insulating layer 23 and the heat dissipation base 30 in the thickness direction of the bonding material S.

As a result, it is possible to avoid a defect such that a crack or the like occurs in the bonding material S itself by a heat cycle due to narrowing of a width of the bonding material S.

Furthermore, in the present embodiment, in the cross section, the distance (length L5) from the first conductor layer 21 to the peripheral edge of the first surface 23a of the insulating layer 23 is longer than the distance (length L3) from the second conductor layer 22 to the peripheral edge of the second surface 23b of the insulating layer 23.

As a result, even if the spread of the bonding material S increases and the contact area between the bonding material S and the second surface 23b of the insulating layer 23 increases, the insulating distance along the surface of the insulating layer 23 can be secured.

Furthermore, in the present embodiment, the bonding material S covers the second conductor layer 22 and is in contact with the insulating layer 23.

Here, in the present embodiment, as described above, even if the bonding material S comes into contact with the second surface 23b of the insulating layer 23, it is possible to suppress the occurrence of the crack C in the insulating layer 23. Therefore, by covering the second conductor layer 22 with the bonding material S, heat dissipation from the semiconductor element 10 to the heat dissipation base 30 via the wiring board 20 (second conductor layer 22) can be enhanced.

### First Modification of Embodiment

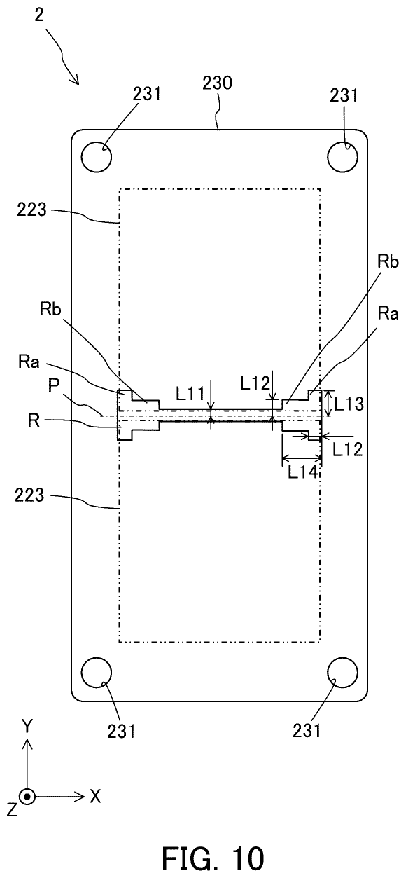

FIG. 10 is a plan view illustrating the solder resist R on a heat dissipation base 230, according to a first modification of the embodiment.

A semiconductor module 2 illustrated in FIG. 10 includes the semiconductor element 10, the wiring board 20, the case 40, the sealing material 50, and the like, similarly to the semiconductor module 1 illustrated in FIGS. 1 and 2. However, those are not illustrated in FIG. 10.

As illustrated in FIG. 10, in the first modification, only two wiring boards (insulating layer 223 illustrated as dash-double-dot line that is imaginary line) aligned in the Y direction are arranged. Therefore, the heat dissipation base 230 illustrated in FIG. 10 has a rectangular shape in plan view that is longer and thinner in the Y direction than the heat dissipation base 30 illustrated in FIG. 5. In the heat dissipation base 230, fastening holes 231 are provided at four corners in plan view.

The solder resist R is arranged over an entire space between the adjacent insulating layers 223. Furthermore, the solder resist R includes the longitudinal direction wide portion Ra and the lateral direction wide portion Rb, in a portion where corners of the two insulating layers 223 are adjacent to each other. The longitudinal direction wide portion Ra extends in a longitudinal direction (Y direction) of the heat dissipation base 230, and the lateral direction wide portion Rb extends in a lateral direction (X direction) of the heat dissipation base 230. In the solder resist R, a width (length L12) of the longitudinal direction wide portion Ra and the lateral direction wide portion Rb is longer than a width (length L11) from intermediate positions P of the two insulating layers 223 in a portion where sides of the two insulating layers 223 are adjacent to each other. Furthermore, a length (L13) of the longitudinal direction wide portion Ra extending in the longitudinal direction (Y direction) is longer than the widths (length L12) from the intermediate position P of the longitudinal direction wide portion Ra and the lateral direction wide portion Rb. Furthermore, a length (L14) of the lateral direction wide portion Rb extending in the lateral direction (X direction) is longer than the length (L13) of the longitudinal direction wide portion Ra extending in the longitudinal direction (Y direction).

### Second Modification of Embodiment

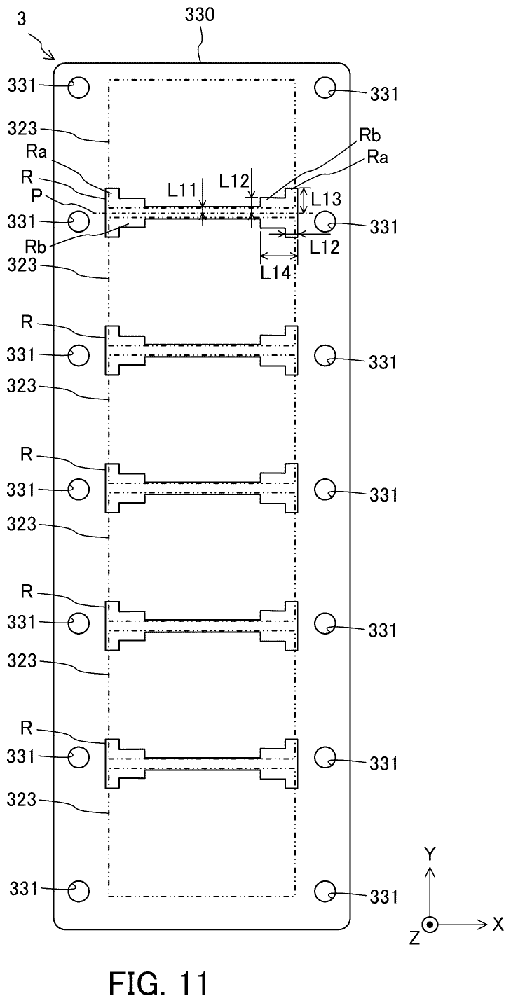

FIG. 11 is a plan view illustrating the solder resist R on a heat dissipation base 330, according to a second modification of the embodiment.

A semiconductor module 3 illustrated in FIG. 11 includes the semiconductor element 10, the wiring board 20, the case 40, the sealing material 50, and the like, similarly to the semiconductor module 1 illustrated in FIGS. 1 and 2. However, those are not illustrated in FIG. 11.

As illustrated in FIG. 11, in the second modification, only six wiring boards (insulating layer 323) aligned in the Y direction are arranged. Therefore, the heat dissipation base 230 illustrated in FIG. 11 has a rectangular shape in plan view that is further longer and thinner in the Y direction than the heat dissipation base 230 illustrated in FIG. 10. In the heat dissipation base 330, seven fastening holes 331 are provided to be aligned in the Y direction, at an end on one side and an end on another side in the X direction.

The solder resist R is arranged over an entire space between the adjacent insulating layers 323. Furthermore, the solder resist R includes the longitudinal direction wide portion Ra and the lateral direction wide portion Rb, in a portion where corners of the insulating layers 323 are adjacent to each other. The longitudinal direction wide portion Ra extends in a longitudinal direction (Y direction) of the heat dissipation base 330, and the lateral direction wide portion Rb extends in a lateral direction (X direction) of the heat dissipation base 330. In the solder resist R, the width (length L12) of the longitudinal direction wide portion Ra and the lateral direction wide portion Rb is longer than the width (length L11) from intermediate positions P of the two insulating layers 323 in a portion where sides of the two insulating layers 323 are adjacent to each other. Furthermore, the length (L13) of the longitudinal direction wide portion Ra extending in the longitudinal direction (Y direction) is longer than the widths (length L12) from the intermediate position P of the longitudinal direction wide portion Ra and the lateral direction wide portion Rb. Furthermore, a length (L14) of the lateral direction wide portion Rb extending in the lateral direction (X direction) is longer than the length (L13) of the longitudinal direction wide portion Ra extending in the longitudinal direction (Y direction).

Note that, as described above, the bonding material S at the time of melting gathers at the center of the heat dissipation base 330 in plan view due to the gravity, and the insulating layer 323 easily comes into contact with the bonding material S. Therefore, the solder resist R may be provided only at the center of the heat dissipation base 330 in the longitudinal direction (for example, between third insulating layer 323 and fourth insulating layer 323 from Y direction positive side) or only at the center and near the center of the heat dissipation base 330 in the longitudinal direction (for example, between second insulating layer 323 and third insulating layer 323 from Y direction positive side and between fourth insulating layer 323 and fifth insulating layer 323 from Y direction positive side). Furthermore, the solder resist R may be wider than other portions at the center or near the center of the heat dissipation base 330 in the longitudinal direction.

### Other Embodiments

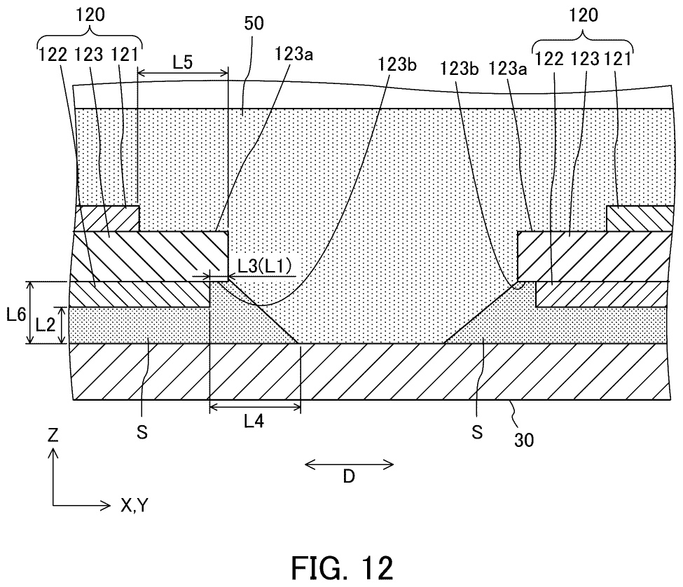

FIG. 12 is a cross-sectional view (corresponding to line II-II in FIG. 1) illustrating a wiring board 120 or the like according to the other embodiments.

The present embodiment can be similar to the semiconductor module 1 according to the embodiment described above, except that the solder resist R is omitted and some of dimensions of parts of the wiring board 120 are different. Therefore, description of overlapping matters is omitted.

The wiring board 120 illustrated in FIG. 12 has a rectangular shape in plan view, similarly to the wiring board 20 described above and includes a first conductor layer 121, a second conductor layer 122, and an insulating layer 123. Note that the number of wiring boards 120 may be four as illustrated in FIG. 1, may be two as in the first modification illustrated in FIG. 10, or may be six as in the second modification illustrated in FIG. 11 and is not particularly limited.

In the present embodiment, in a cross section (cross section in FIG. 12) passing through a corner of the insulating layer 123 in plan view and the corner of the second conductor layer 122, a distance (length L3) from the second conductor layer 122 to a peripheral edge of the insulating layer 123 (for example, corner in diagonal direction D) is equal to or less than a thickness (length L2) of a bonding material S between the second conductor layer 122 and a heat dissipation base 30. Therefore, as in the embodiment described above, in the cross section, the distance (length L1) from the second conductor layer 122 to the peripheral edge of the bonding material S on a second surface 123b of the insulating layer 123 is also equal to or less than the thickness (length L2) of the bonding material S between the second conductor layer 122 and the heat dissipation base 30.

To shorten the length L3 in this way, it is preferable to reduce the size of the insulating layer 123 so that the peripheral edge of the insulating layer 123 approaches the second conductor layer 122 or to enlarge the second conductor layer 122 so as to approach the peripheral edge of the insulating layer 123. By enlarging the second conductor layer 122, heat dissipation of the semiconductor element 10 can be enhanced.

Other relationships in the length are similar to those in the embodiment described above. However, in particular, the distance (length L3) from the second conductor layer 122 to the peripheral edge (for example, corner) of the insulating layer 123 becomes shorter so that it becomes difficult to secure an insulating distance, for example, because the bonding material S spreads over an outer peripheral surface of the insulating layer 123.

From this viewpoint, in the cross section in FIG. 12, it is particularly effective that a distance (length L4) from the second conductor layer 122 to the peripheral edge of the bonding material S on the heat dissipation base 30 in plan view is shorter than a distance (length L5) from the first conductor layer 121 to the peripheral edge of the first surface 123a of the insulating layer 123 and the distance (L5) from the first conductor layer 121 to the peripheral edge of the first surface 123a of the insulating layer 123 is longer than the distance (length L3) from the second conductor layer 122 to the peripheral edge of the second surface 123b of the insulating layer 123.

In the other embodiments described above, in the cross section in FIG. 12 (cross section passing through corner of insulating layer 123 in plan view and corner of second conductor layer 122), the distance (length L3) from the second conductor layer 122 to the peripheral edge of the insulating layer 123 (for example, corner in diagonal direction D) is equal to or less than the thickness (length L2) of the bonding material S between the second conductor layer 122 and the heat dissipation base 30.

Therefore, as in the embodiment described above, in the cross section in FIG. 12, the distance (length L1) from the second conductor layer 122 to the peripheral edge of the bonding material S on the second surface 123b of the insulating layer 123 can be equal to or less than the thickness (length L2) of the bonding material S between the second conductor layer 122 and the heat dissipation base 30. Therefore, at the time when the bonding material S is cooled, even if the insulating layer 123 having a relatively small linear expansion coefficient is pulled by the bonding material S and the second conductor layer 122 having a relatively large linear expansion coefficient, a stress concentrating at a boundary between the bonding material S and the second conductor layer 122 in the insulating layer 123 can be relaxed. Therefore, according to the present embodiment, it is possible to suppress occurrence of a crack C in the insulating layer 123 of the wiring board 120.

The semiconductor module according to the present invention is not limited to the embodiment described above, and various changes, substitutions, and modifications may be made without departing from the spirit of the technical concept. Furthermore, if the technical idea can be achieved in another manner due to the progress of the technology or by another derived technology, the technical idea may be carried out by using the manner. Therefore, the claims cover all embodiments that may be included within the scope of the technical idea.

For example, as in the other embodiments, in the cross section in FIG. 12, the distance (length L3) from the second conductor layer 122 to the peripheral edge (for example, corner) of the insulating layer 123 may be equal to or less than the thickness (length L2) of the bonding material S between the second conductor layer 122 and the heat dissipation base 30, and the solder resist R may be provided as in the embodiment. Furthermore, in the heat dissipation bases 30, 230, and 330, a base plate having a flat plate shape is warped by press working or the like, and the lower surface is warped to be a convex curved surface, and the upper surface bonded to the wiring boards 20 and 120 is warped to be a concave curved surface. However, the shape of the heat dissipation bases 30, 230, and 330 in the present invention is not limited to such a shape.

Hereinafter, some inventions described in the specification and drawings of the present application will be additionally described.

### Supplementary Note 1

A semiconductor module including:
a semiconductor element;
a wiring board on which the semiconductor element is mounted; and
a heat dissipation base bonded to the wiring board with a bonding material, in which
the wiring board includes an insulating layer, a first conductor layer provided on a first surface of the insulating layer on a side of the semiconductor element, and a second conductor layer provided on a second surface of the insulating layer on a side of the heat dissipation base,
in a cross section passing through a corner of the insulating layer in plan view and the corner of the second conductor layer, a distance from the second conductor layer to a peripheral edge of the bonding material on the second surface is equal to or less than a thickness of the bonding material between the second conductor layer and the heat dissipation base,
a non-bonded portion is provided around the bonding material on the heat dissipation base,
wettability between the bonding material and the second conductor layer and wettability between the bonding material and the heat dissipation base are larger than wettability between the non-bonded portion and the bonding material, and
in the cross section, a distance from the second conductor layer to the non-bonded portion in plan view is equal to or less than a distance from the second conductor layer to a peripheral edge of the insulating layer on the second surface.

### Supplementary Note 2

A semiconductor module including:
a semiconductor element;
a wiring board on which the semiconductor element is mounted; and
a heat dissipation base bonded to the wiring board with a bonding material, in which
the wiring board includes an insulating layer, a first conductor layer provided on a first surface of the insulating layer on a side of the semiconductor element, and a second conductor layer provided on a second surface of the insulating layer on a side of the heat dissipation base, and
in a cross section passing through a corner of the insulating layer in plan view and the corner of the second conductor layer, a distance from the second conductor layer to a peripheral edge of the insulating layer on the second surface is equal to or less than a thickness of the bonding material between the second conductor layer and the heat dissipation base.

### Supplementary Note 3

The semiconductor module according to supplementary note 1 or 2, further including:
a plurality of the wiring boards, in which
the corner of the insulating layer is adjacent to the another insulating layer.

### Supplementary Note 4

The semiconductor module according to any one of supplementary notes 1 to 3, in which
in the cross section, a distance from the second conductor layer to the peripheral edge of the bonding material on the heat dissipation base in plan view is shorter than a distance from the first conductor layer to the peripheral edge of the insulating layer on the first surface.

### Supplementary Note 5

The semiconductor module according to any one of supplementary notes 1 to 4, in which
in the cross section, the distance from the second conductor layer to the peripheral edge of the bonding material on the heat dissipation base in plan view is longer than a distance between the insulating layer and the heat dissipation base in a thickness direction of the bonding material.

### Supplementary Note 6

The semiconductor module according to any one of supplementary notes 1 to 5, in which
in the cross section, the distance from the first conductor layer to the peripheral edge of the insulating layer on the first surface is longer than the distance from the second conductor layer to the peripheral edge of the insulating layer on the second surface. cl Supplementary Note 7

The semiconductor module according to any one of supplementary notes 1 to 6, in which
the bonding material covers the second conductor layer and has contact with the insulating layer.

### Supplementary Note 8

The semiconductor module according to supplementary note 1, in which
wettability between the non-bonded portion and the bonding material is lower than wettability between the insulating layer and the bonding material.

As described above, the present invention has an effect of suppressing occurrence of a crack in an insulating layer of a wiring board, and is particularly useful for an industrial or electrical inverter device.

What is claimed is:

1. A semiconductor module, comprising:
a wiring board;
a semiconductor element mounted on a first side of the wiring board; and
a heat dissipation base bonded to the wiring board on a second side of the wiring board opposite to the first side, via a bonding material; wherein:
the wiring board includes an insulating layer having a first surface and a second surface respectively located on the first side and the second side of the wiring board, a first conductor layer provided on the first surface of the insulating layer and a second conductor layer provided on the second surface of the insulating layer; and
in a cross section passing through a corner of the insulating layer and a corner of the second conductor layer in a plan view of the semiconductor module, a distance in a horizontal direction parallel to the first surface of the insulating layer from the second conductor layer to a peripheral edge of the insulating layer on the second surface is equal to or less than a thickness of the bonding material between the second conductor layer and the heat dissipation base.

2. A semiconductor module, comprising:
a wiring board;
a semiconductor element mounted on a first side the wiring board; and
a heat dissipation base bonded to the wiring board on a second side of the wiring board opposite to the first side, via a bonding material; wherein:
the wiring board includes an insulating layer having a first surface and a second surface respectively located on the first side and the second side of the wiring board, a first conductor layer provided on the first surface of the insulating layer, and a second conductor layer provided on the second surface of the insulating layer;
in a cross section passing through a corner of the insulating layer and a corner of the second conductor layer in a plan view of the semiconductor module, a distance in a horizontal direction parallel to the first surface of the insulating layer from the second conductor layer to a peripheral edge of the bonding material on the second surface is equal to or less than a thickness of the bonding material between the second conductor layer and the heat dissipation base;
the heat dissipation base includes a non-bonded region provided around the bonding material;
wettability between the bonding material and the second conductor layer, and wettability between the bonding material and the heat dissipation base, are greater than wettability between the non-bonded region and the bonding material; and
in the cross section, in the horizontal direction, a distance from the second conductor layer to the non-bonded region is equal to or less than a distance from the second conductor layer to a peripheral edge of the insulating layer on the second surface.

3. The semiconductor module according to claim 2, wherein:
the wiring board is provided in plurality; and
the corner of the insulating layer is adjacent to an insulating layer of another wiring board.

4. The semiconductor module according to claim 2, wherein in the cross section, in the horizontal direction, a distance from the second conductor layer to the peripheral edge of the bonding material on the heat dissipation base is shorter than a distance from the first conductor layer to the peripheral edge of the insulating layer on the first surface.

5. The semiconductor module according to claim 2, wherein in the cross section, in the horizontal direction, the distance from the second conductor layer to the peripheral edge of the bonding material on the heat dissipation base is greater than a distance between the insulating layer and the heat dissipation base in a thickness direction of the bonding material.

6. The semiconductor module according to claim 2, wherein in the cross section, in the horizontal direction, the distance from the first conductor layer to the peripheral edge of the insulating layer on the first surface is greater than the distance from the second conductor layer to the peripheral edge of the insulating layer on the second surface.

7. The semiconductor module according to claim 2, wherein the bonding material is in contact with the insulating layer and covers the second conductor layer.

8. The semiconductor module according to claim 2, wherein wettability between the non-bonded region and the bonding material is lower than wettability between the insulating layer and the bonding material.
